(19) United States
(12) Patent Application Publication
(10) Pub. No.: US 2011/0186944 A1
(43) Pub. Date: Aug. 4, 2011

(54) Micromechanical Structure and Method for Setting the Working Gap Width of a Micromechanical Structure

(76) Inventors: Thomas Friedrich, Erfurt (DE); Daniel Christoph Meisel, Vaihingen An Der Enz (DE); Carsten Raudzis, Frickenhausen (DE)

(21) Appl. No.: 13/055,298

(22) PCT Filed: Jun. 15, 2009
(86) PCT No.: PCT/EP2009/057387

§ 371 Date: Apr. 21, 2011

(30) Foreign Application Priority Data
Jul. 30, 2008 (DE) 10 2008 040 854.9

(51) Int. Cl. H01L 29/84; H01L 21/02

(52) U.S. Cl. 257/418; 438/50; 257/E29.324; 257/E21.002

(57) ABSTRACT

A micromechanical structure, includes at least two structure sections configured to bound a working gap, the at least two structure sections being movable relative to one another, and a working gap width setting device configured to broaden the at least one working gap by movement of a first structure section of the at least two structure sections relative to a second structure section of the at least two structure section, the first structure section is stationary relative to a reference point during operation of the micromechanical structure and (ii) the second structure section is movable relative to the reference point during operation.

### PRIOR ART

The invention relates to a micromechanical structure according to the precharacterizing clause of claim 1, and to a method for setting the working gap width of a micromechanical structure according to the precharacterizing clause of claim 10.

For a multiplicity of applications in microsystem engineering, it is necessary to provide working gaps with a high aspect ratio in semiconductor substrates, that is to say having a high quotient of the gap depth to the gap width. U.S. Pat. No. 6,136,630 and DE 198 52 878 disclose solutions for increasing the aspect ratio.

WO 03/043189 describes an electromechanical resonator having a micromechanical structure. A moving structure element is prestressed with respect to a stationary structure element, in order to reduce the working gap width, by application of an electrical field.

DE 10 2004 053 103 A1 discloses the gap width being reduced by the use of at least one spring, with the spring being attached at a clamping-in point and having internal prestressing which results from lamination of the base material of the spring, and being released into a length change, in order to minimize the gap width.

In the case of micromechanical sensors or actuators in which small and standard working gap widths are present for process reasons, there are essentially two difficulties. For example, a non-linear and therefore unstable behavior can be observed in the case of micromechanical structures in the form of comb drives and with standard gap widths. Furthermore, known sensors and actuators with a very small gap width are subject to the problem that only a small mechanical working amplitude can be achieved for acceleration and rotation rate sensors.

### DISCLOSURE OF THE INVENTION

### Technical Object

The invention is based on the object of proposing an alternative micromechanical structure, by means of which comparatively large mechanical working amplitudes can be achieved. The object also comprises proposing a correspondingly optimized method for increasing the working amplitude.

### Technical Solution

This object is achieved with regard to the micromechanical structure by the features of claim 1, and with regard to the method by the features of claim 10. Advantageous developments of the invention are specified in the dependent claims. All combinations of at least two features disclosed in the description, the claims and/or the figures fall within the scope of the invention. In order to avoid repetitions, features disclosed according to the method are considered to have been disclosed and can be claimed according to the apparatus. Features disclosed according to the apparatus are likewise considered to have been disclosed and can be claimed according to the method.

The invention is based on the idea of proposing a micromechanical structure in which the working gap (working trough) is not reduced in size, as in the prior art, after the introduction of the working gap into a semiconductor material, in particular by means of an etching process, but, instead of this, the gap width can be enlarged by suitable means. In this case, in the case of a micromechanical structure designed according to the concept of the invention, that (semiconductor) structure section which is stationary with respect to a reference point during operation of the micromechanical structure is moved relative to that (semiconductor) structure section which can be moved relative to the reference point during operation of the micromechanical structure. This allows a large mechanical working amplitude to be achieved, particularly in the case of acceleration and rotation rate sensors, or else in the case of actuators, retrospectively. It is also possible, if the micromechanical structure is appropriately designed, as will be explained later as well, to achieve a linear response from a corresponding actuator or sensor, which in particular is structured like a comb, by the provision of non-uniform gap widths. The reference point can either itself be moving or stationary. The reference point is preferably a component of an apparatus which is equipped with the microstructure according to the invention. For example, the reference point may be formed by a frame of a rotating frame sensor, which frame is mounted such that it can rotate relative to a sensor housing.

In summary, the essence of the invention is therefore to enlarge the functionally relevant working gap in micromechanical structures after gap production. For the purposes of the invention, a working gap in a micromechanical structure which is used as an actuator means the gap into which the moving (actively movable) structure section can be moved. In the case of a sensor, a working gap means the gap which is bounded by structure sections between which an electrical capacitance is measured. In this case, when the working gap becomes smaller, the capacitance increases by movement of the movable structure section in the direction of the stationary structure section.

A development of the invention advantageously provides that the means broaden the working gap such that the working gap has a non-uniform gap width. In other words, broadening of the working gap at least in places results in a different gap width at least two different points on the working gap, and therefore in a linear response. In the case of a comb drive, the working gap sections which extend in the direction of the longitudinal extent of the comb drive are in this case preferably broader (transversely with respect to the longitudinal extent) than those working gap sections which extend transversely with respect to the longitudinal extent of the comb drive.

According to a simplest embodiment, the working gap is only one-dimensional, that is to say it is broadened by movement of at least one structure section in a single direction. However, an embodiment is also feasible, particularly in the case of a working gap which is not in the form of a straight line but, for example, runs over at least one corner, in which the working gap is broadened two-dimensionally, in particular by movement of at least one structure section, which is stationary during operation of the micromechanical structure, in two directions, or preferably by movement of at least two or more structure elements in two directions, which preferably run at right angles to one another.

There are various options for the configuration of the means for broadening the working gap. In principle, it is feasible to use the same means (however with an opposite effect) as those used to narrow the working gap in the prior art. An embodiment is very particularly preferable, in which the means are designed to broaden the working gap by production of an electromagnetic field, that is to say by the use of electrostatic forces. Additionally or alternatively, the means can be designed to broaden the working gap by the use of at least one spring. In this case, an embodiment is very particularly preferable in which the spring is designed in the form as described in DE 10 2004 058 103 A1, that is to say the spring is provided with a coating which ensures internal prestressing of the spring.

In order to provide sufficient space within the micromechanical structure to enlarge the working gap, an embodiment is preferred in which the at least one working gap to be broadened has at least one associated auxiliary gap, which is narrowed, in particular completely closed, with the aid of the means for broadening the working gap.

According to one particularly preferred embodiment of the micromechanical structure, the structure sections which bound the working gap are designed like a comb, with the comb-like structure sections engaging in one another like a tooth system, with a distance between them. In order to enlarge the working gap, those structure sections are moved away from the respective other structure section which is stationary during operation of the micromechanical structure. In this case, the working gap is particularly preferably enlarged only one-dimensionally, preferably such that the initially mentioned non-uniform working gap widths are achieved.

A development of the invention advantageously provides that the working gap is in the form of an (annular) gap which runs around the structure section which is stationary during operation of the mechanical structure. A plurality, in particular four, structure sections which are stationary during operation are preferably provided, which can be moved towards one another with the aid of the means for broadening the working gap, in order to broaden the working gap, preferably uniformly.

In one very particularly preferred embodiment, the working gap can be broadened by parallel movement of a plurality of structure sections which are stationary during operation of the micromechanical structure. In this case, each structure section which can be moved preferably has an associated auxiliary gap, which is preferably completely closed by movement of the stationary structure sections. The described embodiment is particularly advantageous because the auxiliary gap widths are additive, thus allowing the working gap to be broadened to a particularly major extent.

The invention also leads to a method for setting a working gap, which is bounded by at least two structure sections which can be moved relative to one another, of a micromechanical structure, in particular of a sensor or an actuator. The invention provides that the working gap is broadened retrospectively by movement of the at least one structure section, which is stationary during operation of the micromechanical structure. That is to say, in other words, the stationary reference structure section is moved, rather than the structure section which moves during operation of the micromechanical structure.

### BRIEF DESCRIPTION OF THE DRAWINGS

Further advantages, features and details of the invention will become evident from the following description of preferred exemplary embodiments and from the drawings, in which:

FIG. 1 shows a micromechanical comb structure immediately after the production of the working gaps, in the not yet broadened state,

FIG. 2 shows a micromechanical comb structure as shown in FIG. 1 after retrospective working gap broadening,

FIG. 3 shows a detail of the micromechanical comb structure as shown in FIG. 1,

FIG. 4 shows a detail of the broadened micromechanical comb structure as shown in FIG. 2,

FIG. 5 shows an alternative micromechanical structure with a circumferential working gap, before broadening,

FIG. 6 shows the micromechanical structure as shown in FIG. 5 after broadening of the working gap,

FIG. 7 shows a further, alternative exemplary embodiment of a micromechanical structure with a working gap, with a plurality of structure sections being provided which are stationary during operation of the micromechanical structure and can be moved by parallel movement to the state shown in FIG. 8, and

FIG. 8 shows the micromechanical structure as shown in FIG. 7 with a broadened working gap.

### EMBODIMENTS OF THE INVENTION

Identical elements and elements having the same function are provided with the same reference symbols in the figures.

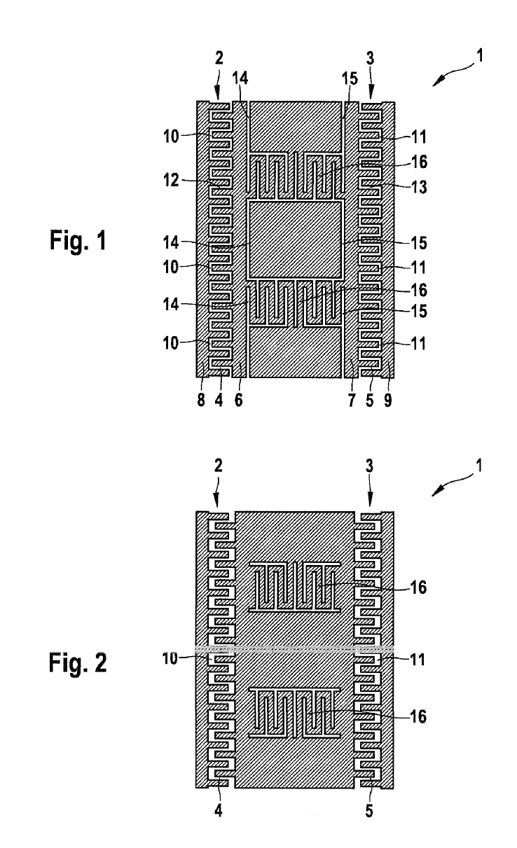

FIG. 1 shows a detail of a micromechanical structure 1 which is optionally used as a sensor or an actuator. The micromechanical structure 1 is formed in the semiconductor material by etching steps. As can be seen from FIG. 1, the micromechanical structure comprises two active structure areas 2, 3, which each have a meandering working gap 4, 5, with the working gaps 4, 5 running parallel to one another. Each of the working gaps 4, 5 is formed between a structure section 6, 7, which is the inner structure section on the plane of the drawing, is like a comb and is stationary during operation of the micromechanical structure 1, and a structure section 8, 9, which is the outer structure section on the plane of the drawing, is like a comb, moves (in the case of an actuator is actively movable) and meshes with the respective stationary structure section 6, 7.

The working gap sections 10, 11 which extend in the direction of the longitudinal extent of the structure areas 2, 3 have the same gap width, after etching of the trough structure, as the working gap sections 12, which extend transversely with respect to the longitudinal extent of the structure areas 2, 3. An electrical field is produced in order to broaden the working gap sections 10, 11 which extend in the direction of the longitudinal extent of the comb-like structure areas 2, 3, such that the structure sections 6, 7, which are the inner structure sections on the plane of the drawing and are stationary during operation of the micromechanical structure 1, are moved towards one another, that is to say away from the associated structure section 8, 9 which moves during operation. This is possible because each stationary structure section 6, 7 has a plurality of associated auxiliary gaps 14, 15, which extend parallel to the working gap sections 10, 11 which extend in the direction of the longitudinal extent of the structure areas 2, 3. The auxiliary gaps 14, 15 are formed within a spring element 16. A mechanical movement mechanism, assisted by spring force, can also be provided, in addition to or as an alternative to the production of an electrical field. The auxiliary gaps 14, 15 are closed on the inside by movement of the structure sections 6, 7, thus resulting in the micromechanical structure 1 as shown in FIG. 2, in which the working gaps 4, 5, to be more precise the working gap sections 10, 11 which extend in the direction of the longitudinal extent of the structure areas 2, 3, are broadened in the direction transversely with respect to the longitudinal extent of the structure areas 2, 3, thus ensuring a greater mechanical amplitude and, in the illustrated exemplary embodiment, a linear response as well.

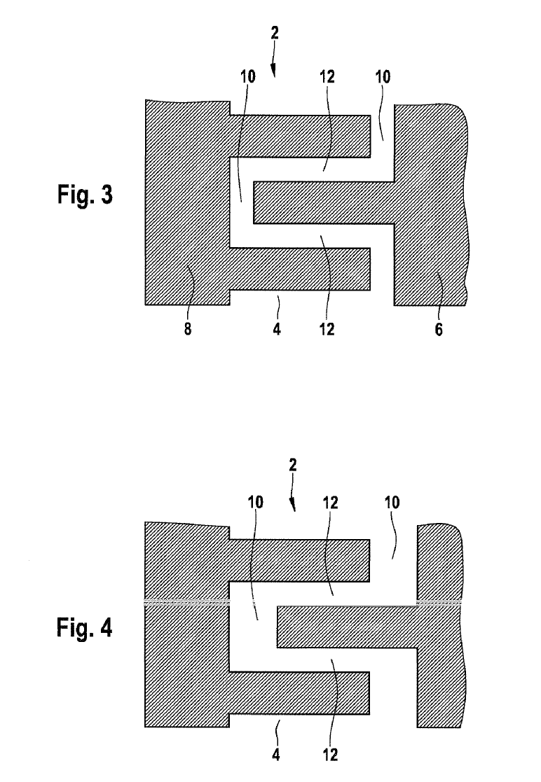

FIGS. 3 and 4 show a detail of the working gap 4 as shown in FIGS. 1 and 2, respectively, before and respectively after the retrospective broadening of the working gap. As can be seen, the working gap 4 has a uniform gap width, in this case of 1.5 μm, before broadening. In other words, the gap width of the working gap section 10 which extends in the direction of the longitudinal extent of the structure area 2 is precisely the same size before broadening as the width of the working gap sections 12 which extend transversely with respect thereto. The working gap section 10 is broadened by movement of the structure section 6, which is stationary during operation, to the right on the plane of the drawing while, in contrast, the width of the working gap sections 12 remains constant. In the exemplary embodiment shown in FIG. 4, the gap width of the working gap section 10 is twice as great as the gap width of the working gap 12.

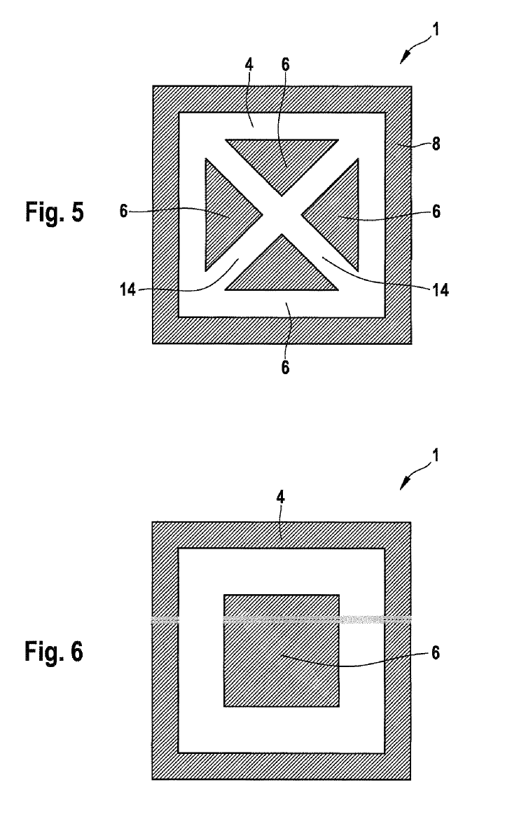

FIGS. 5 and 6 show an alternative exemplary embodiment of a micromechanical structure 1 before and respectively after the broadening of the working gap 4, which in this case is in the form of a circumferential gap. The micromechanical structure 1 comprises an outer structure section 8 and four structure sections 6, which are contoured in a triangular shape and are stationary during operation of the micromechanical structure 1, and between which obliquely running, crossing auxiliary gaps 14 are provided. These are closed by relative movement of the structure sections 6, resulting in two-dimensional enlargement of the circumferential working gap 4, as is shown in FIG. 6. The mechanism for movement of the structure sections 6 may, for example, be in the form of an electrostatic movement mechanism, or a mechanical movement mechanism using at least one spring element.

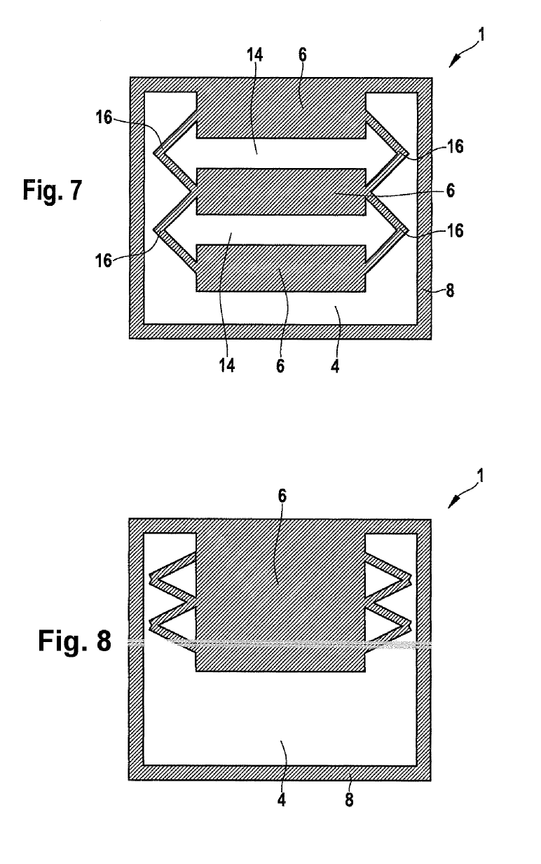

FIGS. 7 and 8 show a further alternative exemplary embodiment of a micromechanical structure. It can be seen that structure sections 6 which run parallel to one another and are stationary during operation of the micromechanical structure. An auxiliary gap is in each case formed between two adjacent structure sections 6 and is closed by moving the structure elements 6 towards one another, as is shown in FIG. 8. The stationary structure sections 6 are mechanically connected to one another via spring elements 16 which produce the movement of the structure sections 6. This results in a working gap 4 as shown in FIG. 8, which is broader than that in FIG. 7.

1. A micromechanical structure, comprising:
at least two structure sections configured to bound a working gap, the at least two structure sections being movable relative to one another; and
a working gap width setting device configured to broaden the at least one working gap by movement of a first structure section of the at least two structure sections relative to a second structure section of the at least two structure sections,
wherein (i) the first structure section is stationary relative to a reference point during operation of the micromechanical structure and (ii) the second structure section is movable relative to the reference point during operation of the micromechanical structure.

2. The micromechanical structure as claimed in claim 1, wherein the working gap width setting device is designed to broaden the at least one working gap such that the at least one working gap has a different gap width at least two points.

3. The micromechanical structure as claimed in claim 1, wherein the working gap width setting device is designed to broaden the at least one working gap one-dimensionally or two-dimensionally.

4. The micromechanical structure as claimed in claim 1, wherein the working gap width setting device is designed to broaden the at least one working gap by production of electrostatic forces.

5. The micromechanical structure as claimed in claim 1, wherein the working gap width setting device is designed to broaden the at least one working gap with at least one spring.

6. The micromechanical structure as claimed in claim 1, wherein the working gap width setting device is designed to broaden the at least one working gap by narrowing at least one auxiliary gap.

7. The micromechanical structure as claimed in claim 1, wherein:
the at least two structure sections are a plurality of combs, and
the working gap width setting device is configured to move the first structure section away from the second structure section.

8. The micromechanical structure as claimed in claim 1, wherein the at least one working gap is a first gap around the first structure section.

9. The micromechanical structure as claimed in claim 1, wherein:
the at least one working gap can be broadened by parallel movement of a plurality of the at least two structure sections, and
the plurality of the at least two structure sections are stationary during operation of the micromechanical structure.

10. A method for setting a working gap of a micromechanical structure, comprising:
bounding the working gap by at least two structure sections; and
broadening the working gap by movement of a first structure section of the at least two structure sections relative to a second structure section of the at least two structure sections,
wherein (i) the first structure section is stationary relative to a reference point during operation of the micromechanical structure and (ii) the second structure section is movable relative to the reference point during operation of the micromechanical structure.

11. A micromechanical structure, in particular a sensor or actuator, having at least one working gap, which is bounded by at least two structure sections, which can be moved relative to one another, and having a means for setting the working gap width, wherein the means are designed to broaden the at least one working gap by movement of the at least one structure section, which is stationary relative to a reference point during operation of the micromechanical structure, relative to the structure section, which moves relative to this reference point during operation.

12. The micromechanical structure as claimed in claim 11, wherein the means are designed to broaden the working gap such that the working gap has a different gap width at least two points.

13. The micromechanical structure as claimed in claim 11, wherein the means are designed to broaden the working gap one-dimensionally or two-dimensionally.

14. The micromechanical structure as claimed in claim 11, wherein the means are designed to broaden the working gap by production of electrostatic forces.

15. The micromechanical structure as claimed in claim 11, wherein the means are designed to broaden the working gap by means of at least one, in particular coated, spring.

16. The micromechanical structure as claimed in claim 11, wherein the means are designed to broaden the working gap by narrowing at least one auxiliary gap.

17. The micromechanical structure as claimed in claim 11, wherein the structure sections, which bound the working gap are in the form of combs, and in that the structure section, which is stationary during operation of the micromechanical structure can be moved away from the structure section which can be moved during operation, by the means.

18. The micromechanical structure as claimed in claim 11, wherein the working gap is in the form of a gap, which runs around the at least one structure section, which is stationary during operation.

19. The micromechanical structure as claimed in claim 11, wherein the working gap can be broadened by parallel movement of a plurality of structure sections, which are stationary during operation of the micromechanical structure.
